(19) United States
(12) Patent Application Publication
(10) Pub. No.: US 2023/0074743 A1
(43) Pub. Date: Mar. 9, 2023

(54) EXTREME ULTRAVIOLET LIGHT GENERATION APPARATUS AND ELECTRONIC DEVICE MANUFACTURING METHOD

(71) Applicant: Gigaphoton Inc., Tochigi (JP)

(72) Inventor: Koutaro MIYASHITA, Oyama-shi (JP)

(73) Assignee: Gigaphoton Inc., Tochigi (JP)

(21) Appl. No.: 17/818,945

(22) Filed: Aug. 10, 2022

(30) Foreign Application Priority Data
Sep. 8, 2021 (JP) 2021-146012

(51) Int. Cl. H05G 2/00; G02B 5/08

(52) U.S. Cl. CPC H05G 2/008; G02B 5/0891

(57) ABSTRACT

An extreme ultraviolet light generation apparatus includes a first chamber, an EUV light concentrating mirror arranged in the first chamber and configured to concentrate extreme ultraviolet light generated at a first point in the first chamber onto a second point, a first planar mirror arranged on an optical path of the extreme ultraviolet light reflected by the EUV light concentrating mirror, a second chamber accommodating the first planar mirror, a flexible tube arranged between the first and second chambers, an alignment optical system arranged at the first chamber and configured to cause alignment light to be incident on the EUV light concentrating mirror, a detector arranged at the second chamber and configured to detect the alignment light reflected by the EUV light concentrating mirror, an actuator configured to change posture of the first planar mirror, and a processor configured to control the actuator based on output of the detector.

### CROSS-REFERENCE TO RELATED APPLICATIONS

The present application claims the benefit of Japanese Patent Application No. 2021-146012, filed on Sep. 8, 2021, the entire contents of which are hereby incorporated by reference.

### BACKGROUND

### 1. Technical Field

The present disclosure relates to an extreme ultraviolet light generation apparatus, and an electronic device manufacturing method.

### 2. Related Art

Recently, miniaturization of a transfer pattern in optical lithography of a semiconductor process has been rapidly proceeding along with miniaturization of the semiconductor process. In the next generation, microfabrication at 10 nm or less will be required. Therefore, the development of an exposure apparatus that combines an extreme ultraviolet (EUV) light generation apparatus that generates EUV light having a wavelength of about 13 nm and reduced projection reflection optics is expected.

As the EUV light generation apparatus, a laser produced plasma (LPP) type apparatus using plasma generated by irradiating a target substance with pulse laser light has been developed.

### LIST OF DOCUMENTS

### Patent Documents

Patent Document 1: Japanese Patent Application Publication No. 2007-109451

Patent Document 2: Japanese Patent Application Publication No. 2001-150164

Patent Document 3: US Patent Application Publication No. 2009/159808

Patent Document 4: US Patent Application Publication No. 2010/140512

Patent Document 5: US Patent Application Publication No. 2012/119116

### SUMMARY

An extreme ultraviolet light generation apparatus according to an aspect of the present disclosure includes a first chamber, an EUV light concentrating mirror arranged in the first chamber and configured to concentrate extreme ultraviolet light generated at a first point in the first chamber onto a second point, a first planar mirror arranged on an optical path of the extreme ultraviolet light reflected by the EUV light concentrating mirror, a second chamber accommodating the first planar mirror, a flexible tube arranged between the first and second chambers, an alignment optical system arranged at the first chamber and configured to cause alignment light to be incident on the EUV light concentrating mirror, a detector arranged at the second chamber and configured to detect the alignment light reflected by the EUV light concentrating mirror, an actuator configured to change posture of the first planar mirror, and a processor configured to control the actuator based on output of the detector.

An electronic device manufacturing method according to another aspect of the present disclosure includes generating extreme ultraviolet light using an extreme ultraviolet light generation apparatus, outputting the extreme ultraviolet light to an exposure apparatus, and exposing a photosensitive substrate to the extreme ultraviolet light in the exposure apparatus to manufacture an electronic device. Here, the extreme ultraviolet light generation apparatus includes a first chamber, an EUV light concentrating mirror arranged in the first chamber and configured to concentrate the extreme ultraviolet light generated at a first point in the first chamber onto a second point, a first planar mirror arranged on an optical path of the extreme ultraviolet light reflected by the EUV light concentrating mirror, a second chamber accommodating the first planar mirror, a flexible tube arranged between the first and second chambers, an alignment optical system arranged at the first chamber and configured to cause alignment light to be incident on the EUV light concentrating mirror, a detector arranged at the second chamber and configured to detect the alignment light reflected by the EUV light concentrating mirror, an actuator configured to change posture of the first planar mirror, and a processor configured to control the actuator based on output of the detector.

An electronic device manufacturing method according to another aspect of the present disclosure includes inspecting a defect of a mask by irradiating the mask with extreme ultraviolet light generated by an extreme ultraviolet light generation apparatus, selecting a mask using a result of the inspection, and exposing and transferring a pattern formed on the selected mask onto a photosensitive substrate. Here, the extreme ultraviolet light generation apparatus includes a first chamber, an EUV light concentrating mirror arranged in the first chamber and configured to concentrate the extreme ultraviolet light generated at a first point in the first chamber onto a second point, a first planar mirror arranged on an optical path of the extreme ultraviolet light reflected by the EUV light concentrating mirror, a second chamber accommodating the first planar mirror, a flexible tube arranged between the first and second chambers, an alignment optical system arranged at the first chamber and configured to cause alignment light to be incident on the EUV light concentrating mirror, a detector arranged at the second chamber and configured to detect the alignment light reflected by the EUV light concentrating mirror, an actuator configured to change posture of the first planar mirror, and a processor configured to control the actuator based on output of the detector.

### BRIEF DESCRIPTION OF THE DRAWINGS

Embodiments of the present disclosure will be described below merely as examples with reference to the accompanying drawings.

FIG. 1 schematically shows the configuration of an LPP EUV light generation system.

FIG. 2 schematically shows the configuration of an EUV light generation system according to a comparative example.

FIG. 3 schematically shows the configuration of the EUV light generation system according to a first embodiment.

FIG. 4 is a sectional view of an EUV light concentrating mirror.

FIG. 5 is a flowchart showing operation of a processor in the first embodiment.

FIG. 6 shows an example of a light intensity distribution output from an optical sensor.

FIG. 7 shows relationship between a position of a first planar mirror and an optical axis of EUV light.

FIG. 8 shows an example of the light intensity distribution output from the optical sensor.

FIG. 9 shows relationship between the position of the first planar mirror and the optical axis of EUV light.

FIG. 10 shows an example of the light intensity distribution output from the optical sensor.

FIG. 11 shows relationship between the position of the first planar mirror and the optical axis of EUV light.

FIG. 12 shows an example of the light intensity distribution output from the optical sensor.

FIG. 13 shows relationship between the position of the first planar mirror and the optical axis of EUV light.

FIG. 14 schematically shows the configuration of the EUV light generation system according to a second embodiment.

FIG. 15 is a flowchart showing operation of the processor in the second embodiment.

FIG. 16 shows an example of the light intensity distribution output from the optical sensor.

FIG. 17 shows relationship between the position of the first planar mirror and the optical axis of EUV light.

FIG. 18 shows an example of the light intensity distribution output from the optical sensor.

FIG. 19 shows relationship between the position of the first planar mirror and the optical axis of EUV light.

FIG. 20 shows an example of the light intensity distribution output from the optical sensor.

FIG. 21 shows relationship between the position of the first planar mirror and the optical axis of EUV light.

FIG. 22 shows an example of the light intensity distribution output from the optical sensor.

FIG. 23 shows relationship between the position of the first planar mirror and the optical axis of EUV light.

FIG. 24 schematically shows the configuration of the EUV light generation system according to a third embodiment.

FIG. 25 schematically shows the configuration of an exposure apparatus connected to the EUV light generation system.

FIG. 26 schematically shows the configuration of an inspection apparatus connected to the EUV light generation system.

### DESCRIPTION OF EMBODIMENTS

### <Content>

1. Overall description of EUV light generation system 11

1.1 Configuration

1.2 Operation
2. Comparative example

2.1 Configuration

2.2 Operation

2.3 Problems of comparative example
3. Example in which alignment light 38 passes through window 39 arranged at first chamber 2a

3.1 Configuration

3.2 Operation

3.3 Effect
4. Example in which alignment light 38 enters first planar mirror 43 arranged in second chamber 42

4.1 Configuration

4.2 Operation

4.3 Effect
5. Example in which alignment light 38 enters second planar mirror 46 arranged in second chamber 42

5.1 Configuration

5.2 Operation

5.3 Effect
6. Others

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numerals, and duplicate description thereof is omitted.

### 1. OVERALL DESCRIPTION OF EUV LIGHT GENERATION SYSTEM 11

1.1 Configuration

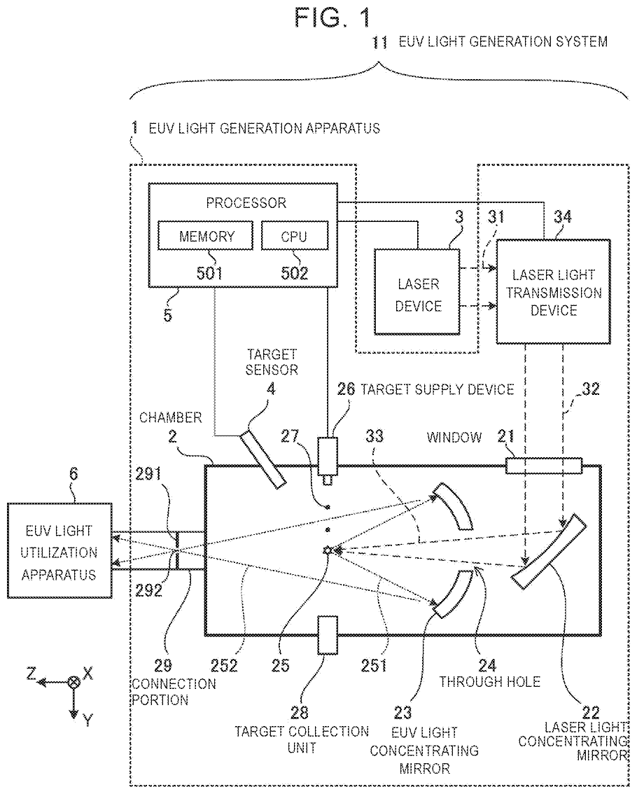

FIG. 1 schematically shows the configuration of an LPP EUV light generation system 11. An EUV light generation apparatus 1 is used together with a laser device 3. In the present disclosure, a system including the EUV light generation apparatus 1 and the laser device 3 is referred to as the EUV light generation system 11. The EUV light generation apparatus 1 includes a chamber 2 and a target supply device 26. The chamber 2 is a sealable container. The target supply device 26 supplies a target 27 containing a target substance into the chamber 2. The material of the target substance may include tin, terbium, gadolinium, lithium, xenon, or a combination of any two or more thereof.

A through hole is formed in a wall of the chamber 2. The through hole is blocked by a window 21 through which pulse laser light 32 output from the laser device 3 passes. An EUV light concentrating mirror 23 having a spheroidal reflection surface is arranged in the chamber 2. The EUV light concentrating mirror 23 has first and second focal points. A multilayer reflection film in which molybdenum and silicon are alternately stacked is formed on a surface of the EUV light concentrating mirror 23. The EUV light concentrating mirror 23 is arranged such that the first focal point is located in a plasma generation region 25 and the second focal point is located at an intermediate focal point 292. A through hole 24 is formed at the center of the EUV light concentrating mirror 23, and pulse laser light 33 passes through the through hole 24.

The direction directing from the first focal point to the second focal point is represented by the Z direction. The traveling direction of the target 27 perpendicular to the Z direction is represented by the Y direction. The direction perpendicular to both the Y direction and the Z direction is represented by the X direction.

The EUV light generation apparatus 1 includes a processor 5, a target sensor 4, and the like. The processor 5 is a processing device including a memory 501 in which a control program is stored, and a central processing unit (CPU) 502 which executes the control program. The processor 5 is specifically configured or programmed to perform various processes included in the present disclosure. The target sensor 4 detects at least one of the presence, trajectory, position, and velocity of the target 27. The target sensor 4 may have an imaging function.

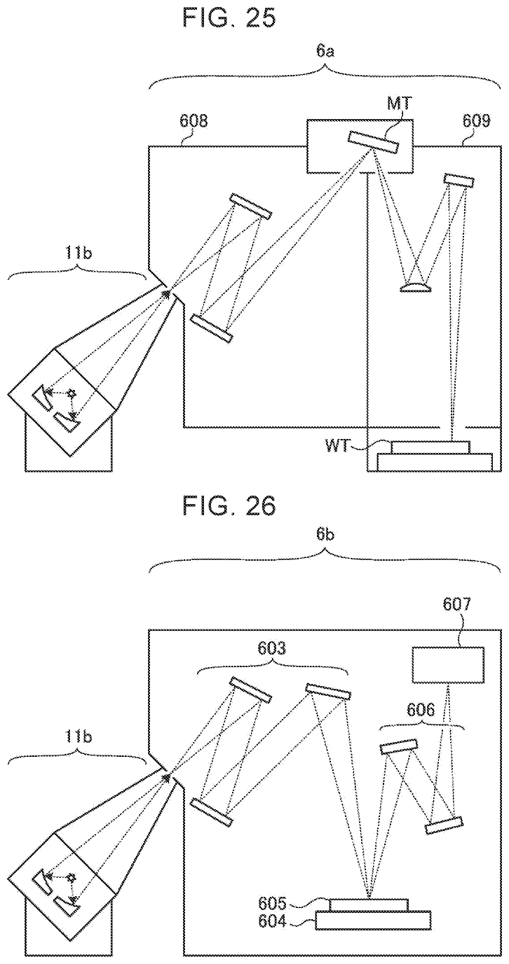

Further, the EUV light generation apparatus 1 includes a connection portion 29 providing communication between the internal space of the chamber 2 and the internal space of an EUV light utilization apparatus 6. An example of the EUV light utilization apparatus 6 will be described later with reference to FIGS. 25 and 26. A wall 291 in which an aperture is formed is arranged in the connection portion 29. The wall 291 is arranged such that the aperture is located at the second focal point of the EUV light concentrating mirror 23.

Furthermore, the EUV light generation apparatus 1 includes a laser light transmission device 34, a laser light concentrating mirror 22, a target collection unit 28 for collecting the target 27, and the like. The laser light transmission device 34 includes an optical element for defining a transmission state of laser light, and an actuator for adjusting the position, posture, and the like of the optical element.
1.2 Operation

Operation of the EUV light generation system 11 will be described with reference to FIG. 1. Pulse laser light 31 output from the laser device 3 enters, via the laser light transmission device 34, the chamber 2 through the window 21 as the pulse laser light 32. The pulse laser light 32 travels along a laser light path in the chamber 2, is reflected by the laser light concentrating mirror 22, and is radiated to the target 27 as the pulse laser light 33.

The target supply device 26 outputs the target 27 toward the plasma generation region 25 in the chamber 2. The target 27 is irradiated with the pulse laser light 33. The target 27 irradiated with the pulse laser light 33 is turned into plasma, and radiation light 251 is radiated from the plasma. EUV light contained in the radiation light 251 is reflected by the EUV light concentrating mirror 23 with higher reflectance than light in other wavelength ranges. Reflection light 252 including the EUV light reflected by the EUV light concentrating mirror 23 is concentrated at the intermediate focal point 292 and output to the EUV light utilization apparatus 6. Here, one target 27 may be irradiated with a plurality of pulses included in the pulse laser light 33.

The processor 5 controls the entire EUV light generation system 11. The processor 5 processes a detection result of the target sensor 4. Based on the detection result of the target sensor 4, the processor 5 controls the timing at which the target 27 is output, the output direction of the target 27, and the like. Further, the processor 5 controls oscillation timing of the laser device 3, a travel direction of the pulse laser light 32, the concentration position of the pulse laser light 33, and the like. The above-described various kinds of control are merely examples, and other control may be added as necessary.

### 2. COMPARATIVE EXAMPLE

2.1 Configuration

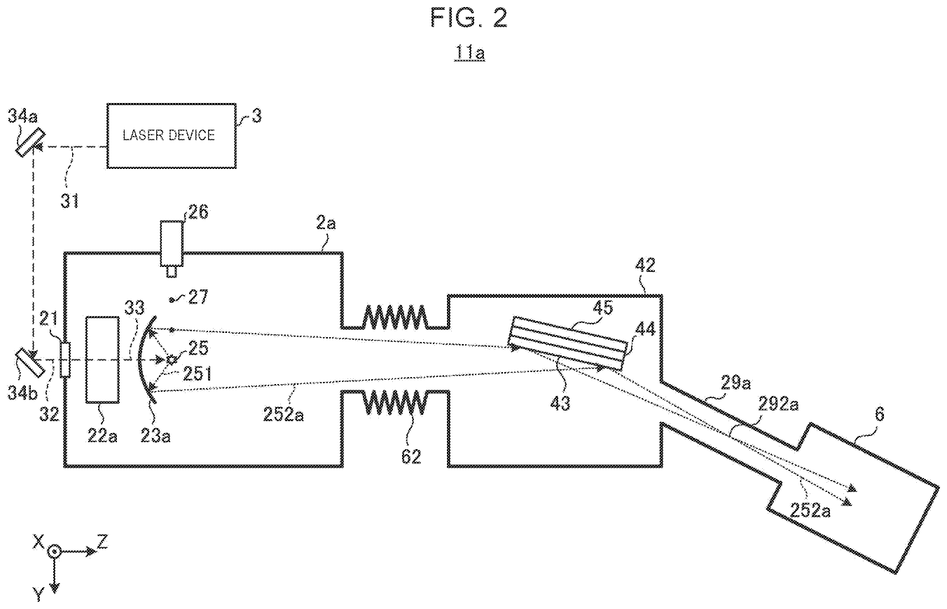

FIG. 2 schematically shows the configuration of an EUV light generation system 11a according to a comparative example. The comparative example of the present disclosure is an example recognized by the applicant as known only by the applicant, and is not a publicly known example admitted by the applicant. As shown in FIG. 2, the EUV light generation system 11a according to the comparative example includes high reflection mirrors 34a, 34b instead of the laser light transmission device 34, and includes a first chamber 2a instead of the chamber 2. The EUV light generation system 11a further includes a second chamber 42 and a flexible tube 62 arranged between the first and second chambers 2a, 42. The flexible tube 62 includes at least partially a flexible material, so that the first and second chambers 2a, 42 can be positioned independently from each other. The flexible material may constitute a bellows tube capable of withstanding a pressure difference between the inside and outside of the flexible tube 62.

In the first chamber 2a, a laser light concentrating optical system 22a is arranged instead of the laser light concentrating mirror 22, and an EUV light concentrating mirror 23a is arranged instead of the EUV light concentrating mirror 23. The EUV light concentrating mirror 23a is configured to concentrate EUV light generated at the first focal point located in the plasma generation region 25 in the first chamber 2a to a second point 292a. The first focal point corresponds to the first point in the present disclosure. FIG. 2 shows only a part of the EUV light concentrating mirror 23a.

A first planar mirror 43 is accommodated in the second chamber 42. The first planar mirror 43 is located between the EUV light concentrating mirror 23a and the second point 292a on the optical path of the EUV light 252a reflected by the EUV light concentrating mirror 23a. The first planar mirror 43 is supported by a holder 44. An actuator 45 attached to the holder 44 is configured to be capable of changing the posture of the first planar mirror 43.

The second chamber 42 is connected to the EUV light utilization apparatus 6 via a connection portion 29a. The second point 292a is located inside the connection portion 29a.
2.2 Operation

The pulse laser light 31 output from the laser device 3 is reflected by the high reflection mirrors 34a, 34b, and passes through the window 21 of the first chamber 2a as the pulse laser light 32. The pulse laser light 32 passes through the laser light concentrating optical system 22a and is concentrated on the plasma generation region 25 as the pulse laser light 33.

The pulse laser light 33 is radiated to the target 27 having reached the plasma generation region 25 after being output from the target supply device 26. Thus, the target 27 is turned into plasma, and radiation light 251 including EUV light is radiated from the plasma. The EUV light concentrating mirror 23a reflects EUV light 252a included in the radiation light 251.

The EUV light 252a passes through the inside of the flexible tube 62 and obliquely enters the first planar mirror 43 in the second chamber 42. The EUV light 252a is reflected by the first planar mirror 43 and enters the EUV light utilization apparatus 6 through the connection portion 29a.
2.3 Problems of Comparative Example

There may be a case that relative positions of the first chamber 2a and the second chamber 42 are displaced due to vibration, thermal deformation, and the like of the first chamber 2a accommodating the EUV light concentrating mirror 23a. When the relative positions of the first chamber 2a and the second chamber 42 are displaced, the optical axis of the EUV light 252a incident on the EUV light utilization apparatus 6 is deviated, and the energy and power of the EUV light usable for the EUV light utilization apparatus 6 are lowered. Although it is conceivable to provide a beam splitter on the optical path of the EUV light 252a and monitor the optical axis of the EUV light 252a by detecting light reflected by the beam splitter, when such a beam splitter is arranged, the energy and power of the EUV light incident on the EUV light utilization apparatus 6 are lowered.

In some embodiments described below, alignment light 38 is incident on the EUV light concentrating mirror 23a from an alignment optical system 36 arranged at the first chamber 2a. The alignment light 38 reflected by the EUV light concentrating mirror 23a is detected by optical sensors 73b, 73c, or 73d arranged at the second chamber 42. Thus, the optical axis of the EUV light 252a can be controlled by detecting deviation of the optical axis of the EUV light 252a with respect to the second chamber 42 and controlling posture of the first planar mirror 43 based on the deviation.

### 3. EXAMPLE IN WHICH ALIGNMENT LIGHT 38 PASSES THROUGH WINDOW 39 ARRANGED AT FIRST CHAMBER 2a

3.1 Configuration

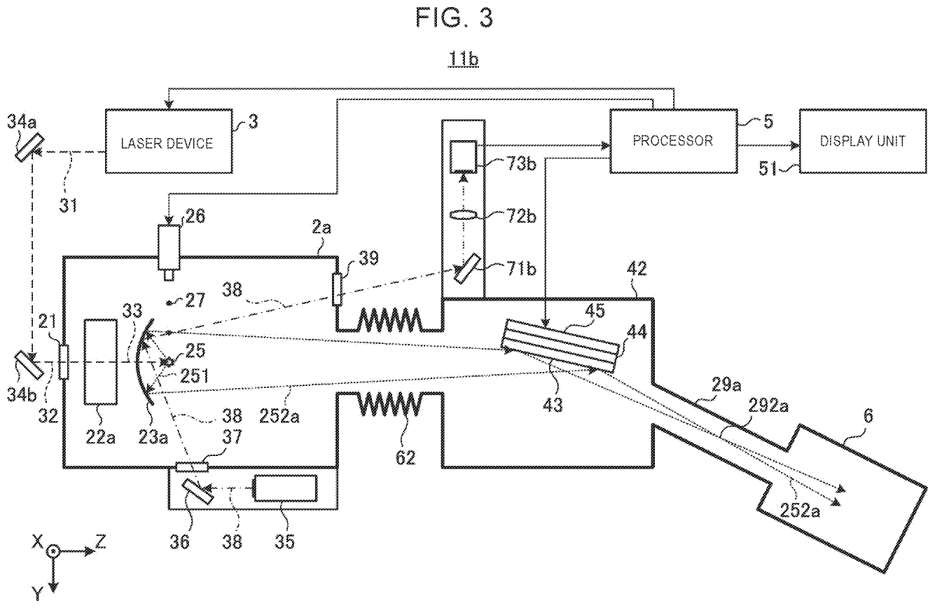

FIG. 3 schematically shows the configuration of an EUV light generation system 11b according to a first embodiment. The EUV light generation system 11b includes an alignment light source 35, the alignment optical system 36, windows 37, 39, a detection optical system 71b, a concentrating optical system 72b, the optical sensor 73b, and a display unit 51.

The alignment light source 35 is a laser light source which outputs the alignment light 38 which is visible light. The alignment optical system 36 is arranged outside the first chamber 2a and configured to cause the alignment light 38 to be incident on the EUV light concentrating mirror 23a. The window 37 is arranged at the first chamber 2a so as to be positioned on the optical path of the alignment light 38 between the alignment optical system 36 and the EUV light concentrating mirror 23a. The window 39 is arranged at the first chamber 2a so as to be positioned on the optical path of the alignment light 38 between the EUV light concentrating mirror 23a and the detection optical system 71b. The window 39 corresponds to the first window in the present disclosure.

The detection optical system 71b, the concentrating optical system 72b, and the optical sensor 73b are arranged outside the second chamber 42. The concentrating optical system 72b is arranged on the optical path of the alignment light 38 between the detection optical system 71b and the optical sensor 73b. The optical sensor 73b which detects the alignment light 38 is arranged at the focal point of the concentrating optical system 72b. The optical sensor 73b corresponds to the detector in the present disclosure.

The display unit 51 includes an image display device. Alternatively, the display unit 51 may be a display lamp having a different lighting pattern between a normal state and an abnormal state.

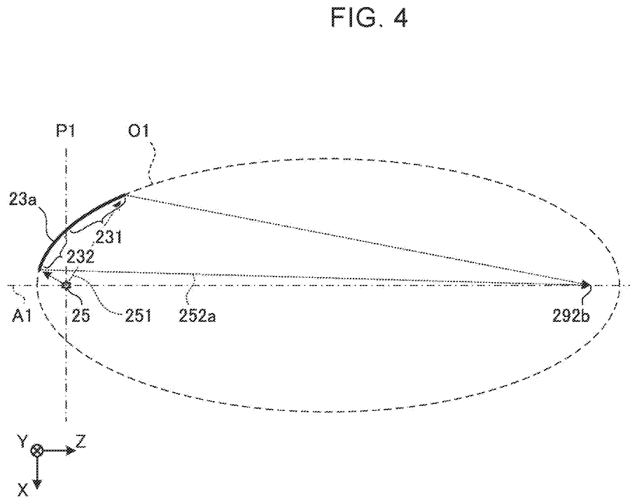

FIG. 4 is a sectional view of the EUV light concentrating mirror 23a. FIG. 3 shows the EUV light concentrating mirror 23a and other components as viewed in the −X direction, while FIG. 4 shows the EUV light concentrating mirror 23a as viewed in the +Y direction. The EUV light concentrating mirror 23a includes a reflection surface coincident with a portion of a spheroid O1 having the first focal point included in the plasma generation region 25, the second focal point 292b farther from the EUV light concentrating mirror 23a than the first focal point, and a virtual rotation axis A1 passing through the first and second focal points. The second point 292a (see FIG. 3) corresponds to a mirror image of the second focal point 292b by the first planar mirror 443. Since the alignment light 38 incident on the EUV light concentrating mirror 23a is reflected in a direction different from the direction orienting from the incident position toward the second focal point 292b, the alignment light 38 does not pass through the second point 292a.

Since the EUV light concentrating mirror 23a is arranged on the −-X side with respect to the rotation axis A1, the optical path of the EUV light 252a reflected by the EUV light concentrating mirror 23a is away from the plasma generation region 25, and the EUV light 252a does not pass through the plasma generation region 25. Such an EUV light concentrating mirror 23a is also referred to as an off-axis elliptical mirror.

The reflection surface of the EUV light concentrating mirror 23a includes a region 231 on a side closer to the second focal point 292b and a region 232 on a side farther from the second focal point 292b, the sides being defined with respect to a virtual plane P1 which is perpendicular to the rotation axis A1 and passes through the plasma generation region 25. The alignment optical system 36 is configured to cause the alignment light 38 to enter the region 231. Since the region 231 is farther from the plasma generation region 25 than the region 232, the region 231 is less likely to be contaminated by the debris of the target substance and scattering of the alignment light 38 is less likely to occur. Thus, the alignment light 38 can be correctly measured.
3.2 Operation

Referring again to FIG. 3, the alignment light 38 output from the alignment light source 35 is directed to the EUV light concentrating mirror 23a by the alignment optical system 36. The alignment light 38 passes through the window 37 to enter the first chamber 2a and is incident on the reflection surface of the EUV light concentrating mirror 23a. The optical path of the alignment light 38 from the window 37 to the EUV light concentrating mirror 23a is away from the plasma generation region 25, and the alignment light 38 does not pass through the plasma generation region 25.

The alignment light 38 is reflected by the EUV light concentrating mirror 23a, passes through the window 39 as traveling on an optical path different from that for the EUV light 252a, exits to the outside of the first chamber 2a, and enters the detection optical system 71b. Therefore, the optical path of the alignment light 38 is away from the first planar mirror 43, and the alignment light 38 is not incident on the first planar mirror 43. On the other hand, the optical path of the EUV light 252a reflected by the EUV light concentrating mirror 23a is away from the window 39, and the EUV light 252a does not enter the window 39.

The detection optical system 71b causes the alignment light 38 to enter the optical sensor 73b through the concentrating optical system 72b. The concentrating optical system 72b concentrates the alignment light 38 onto the light receiving surface of the optical sensor 73b. The optical sensor 73b obtains the light intensity distribution at the light receiving surface and outputs it to the processor 5. The processor 5 specifies the peak position of the light intensity from the light intensity distribution at the light receiving surface of the optical sensor 73b. The peak position is referred to as a position Pn of the alignment light 38 in the following description. Here, n is an integer of 0 or more and increases by 1 each time measurement is performed. A change of the position Pn of the alignment light 38 indicates a change of the optical axis of the alignment light 38.

The position Pn of the alignment light 38 can be represented by, for example, a two-dimensional vector including an X coordinate component and a Y coordinate component.

The processor 5 calculates a target position Φn of the first planar mirror 43 based on a position P0 of the alignment light 38 and controls the actuator 45 based on the target position Φn. The processor 5 causes the display unit 51 to display information indicating whether the EUV light generation system 11b is in the normal state or the abnormal state at the end of the operation thereof.

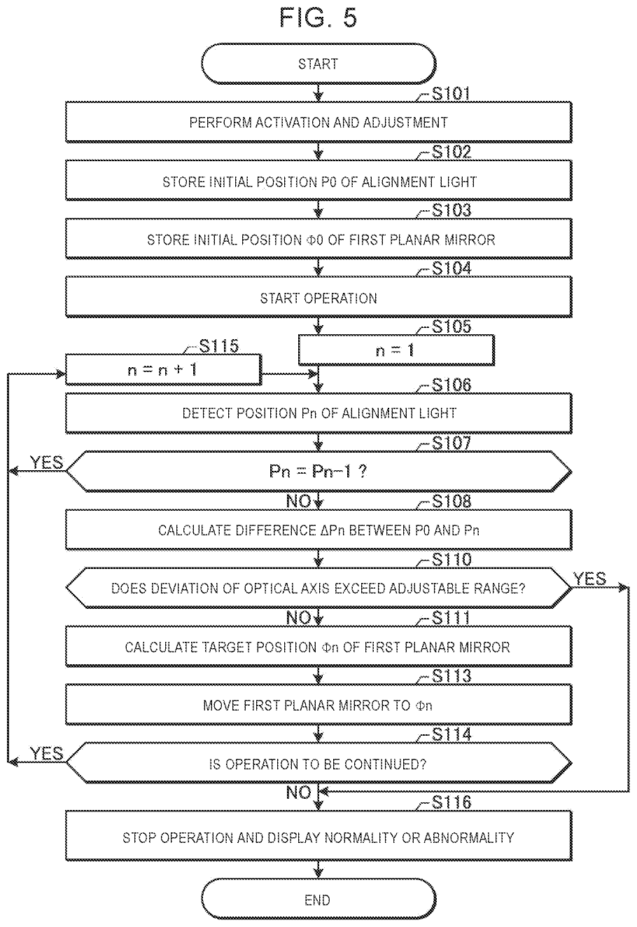

FIG. 5 is a flowchart showing operation of the processor 5 in the first embodiment. The flowchart shown in FIG. 5 includes a procedure of optical axis control of the EUV light 252a using the alignment light 38.

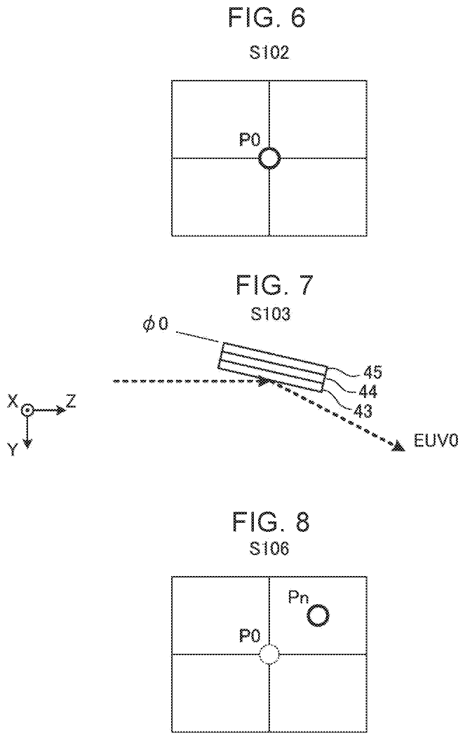

FIGS. 6, 8, 10, and 12 each show an example of the light intensity distribution output from the optical sensor 73b. FIGS. 7, 9, 11, and 13 each show relationship between the position of the first planar mirror 43 and the optical axis of the EUV light 252a. The optical axis of the EUV light 252a means the center axis of the optical path of the EUV light 252a.

In S101, the processor 5 performs activation and adjustment of the EUV light generation system 11b.

In S102, the processor 5 measures the position Pn of the alignment light 38 detected by the optical sensor 73b as an initial position P0 and stores the initial position P0 in the memory 501. The initial position P0 corresponds to the first initial position in the present disclosure. FIG. 6 shows the initial position P0. The initial position P0 is the position of the alignment light 38 in a state in which the adjustment of the EUV light generation system 11b is completed and serves as a reference for subsequent control.

In S103, the processor 5 stores the current posture of the first planar mirror 43 as an initial position 00. The initial position Φ0 corresponds to the second initial position in the present disclosure. When the actuator 45 includes a stepping motor, the current posture of the first planar mirror 43 corresponds to a count number of the stepping motor. When the actuator 45 includes a piezoelectric element, the current posture of the first planar mirror 43 corresponds to a value of the voltage applied to the piezoelectric element.

The actuator 45 is, for example, a two-axis stage and capable of adjusting the posture of the first planar mirror 43 around the X axis and the Y axis.

FIG. 7 shows the initial position Φ0. When the position Pn of the alignment light 38 is the initial position P0 and the current posture of the first planar mirror 43 is at the initial position Φ0, the optical axis of the EUV light 252a reflected by the first planar mirror 43 is represented by EUV0.

In S104, the processor 5 starts operation of the EUV light generation system 11b and starts output of EUV light.

In S105, the processor 5 sets a counter n for counting the number of measurements of the position Pn of the alignment light 38 to 1.

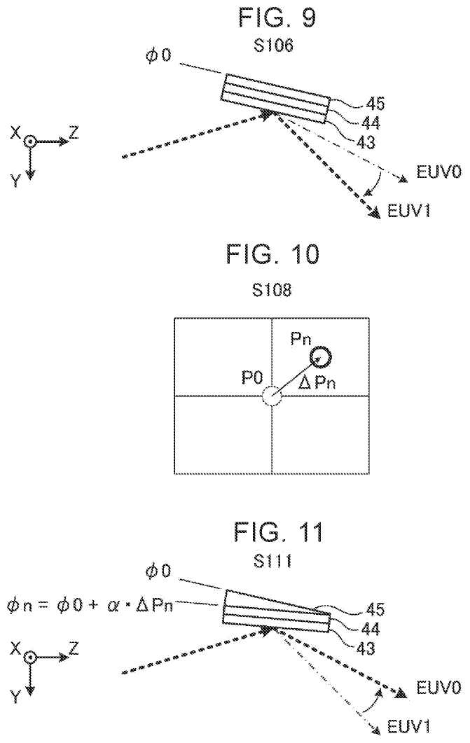

In S106, the processor 5 receives measurement data of the light intensity distribution from the optical sensor 73b and detects the position Pn of the alignment light 38. FIG. 8 shows the position Pn of the newly detected alignment light 38. FIG. 9 shows the new optical axis EUV1 of the EUV light 252a. For example, when the optical axis of the EUV light 252a incident on the first planar mirror 43 is deviated, the optical axis of the EUV light 252a reflected by the first planar mirror 43 is deviated from EUVO to EUV1, and the position Pn of the alignment light 38 changes as shown in FIG. 8.

In S107, the processor 5 determines whether or not the position Pn of the alignment light 38 is equal to the previously measured position Pn-1 of the alignment light 38.

When Pn is equal to Pn−1 (YES in S107), since there is no change of the position Pn of the alignment light 38 and there is no need to return the optical axis of the EUV light 252a, the processor 5 advances processing to S115. The processor 5 updates the value of n by adding 1 to the current value of n in S115, and then, returns processing to S106.

When Pn is different from Pn−1 (NO in S107), the processor 5 advances processing to S108. In S108, the processor 5 calculates the difference ΔPn between the initial position P0 and the position Pn of the alignment light 38 newly detected by the optical sensor 73b by the following equation.

ΔPn=Pn−P0

FIG. 10 shows ΔPn.

In S110, the processor 5 determines whether or not the deviation of the optical axis of the EUV light 252a corresponding to the difference ΔPn exceeds an adjustable range of the first planar mirror 43. For example, a range of ΔPn corresponding to the adjustable range is determined in advance, and it is determined whether or not ΔPn exceeds this range. When the deviation of the optical axis exceeds the adjustable range (YES in S110), the processor 5 advances processing to S116. When the deviation of the optical axis is within the adjustable range (NO in S110), the processor 5 advances processing to S111.

In S111, the processor 5 calculates the target position Φn of the first planar mirror 43 with respect to the initial position Φ0 by the following equation.

Φn=Φ0+α*ΔPn

Here, α is a proportional constant. FIG. 11 shows the target position Φn of the first planar mirror 43. By using the difference ΔPn, it is possible to set the target position ψn of the first planar mirror 43 for returning the optical axis EUV1 of the EUV light 252a to EUV0.

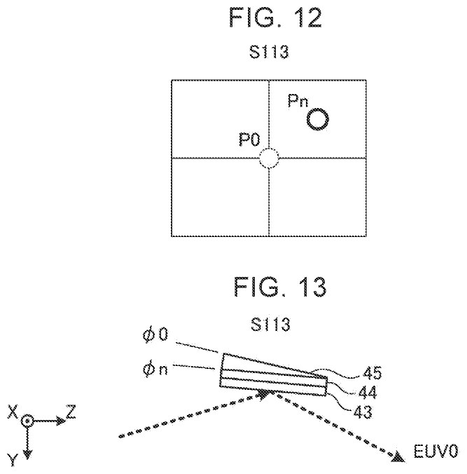

In S113, the processor 5 controls the actuator 45 to move the first planar mirror 43 to the target position Φn. FIG. 12 shows the light intensity distribution output from the optical sensor 73b after the process in S113. FIG. 13 shows relationship between the position of the first planar mirror 43 and the optical axis EUV0 of the EUV light 252a after the process in S113. As shown in FIG. 13, the first planar mirror 43 is controlled to the target position Φn, and the optical axis of the EUV light 252a reflected by the first planar mirror 43 is returned to EUV0. However, since the position Pn of the alignment light 38 is not changed by the control of the first planar mirror 43, the position Pn of the alignment light 38 shown in FIG. 12 is the same as the position Pn of the alignment light 38 detected in S106.

In S114, the processor 5 determines whether or not to continue the operation of the EUV light generation system 11b. When the operation of the EUV light generation system 11b is to be continued (YES in S114), the processor 5 advances processing to S115. When the operation of the EUV light generation system 11b is to be stopped (NO in S114), the processor 5 advances processing to S116.

In S116, the processor 5 stops the operation of the EUV light generation system 11b and causes the display unit 51 to display information indicating normality or abnormality. Abnormality is displayed when processing proceeds to S116 as the determination in S110 is YES, and normality is displayed when processing proceeds to S116 as the determination in S114 is NO. After S116, the processor 5 ends processing of the flowchart.
3.3 Effect

(1) According to the first embodiment, the first chamber 2a accommodating the EUV light concentrating mirror 23a and the second chamber 42 accommodating the first planar mirror 43 which reflects the EUV light 252a incident from the EUV light concentrating mirror 23a are connected by the flexible tube 62. The alignment light 38 is made incident on the EUV light concentrating mirror 23a from the alignment optical system 36 arranged at the first chamber 2a, and the actuator 45 of the first planar mirror 43 is controlled based on the detection result of the alignment light 38 by the optical sensor 73b arranged at the second chamber 42. Accordingly, by detecting the deviation of the optical axis of the EUV light 252a with respect to the second chamber 42 and controlling the optical axis of the EUV light 252a, it is possible to suppress a decrease in the energy and power of EUV light usable for the EUV light utilization apparatus 6.

(2) According to the first embodiment, the first planar mirror 43 is located on the optical path of the EUV light 252a between the EUV light concentrating mirror 23a and the second point 292a. Accordingly, the position of the second point 292a can be controlled by controlling the posture of the first planar mirror 43.

(3) According to the first embodiment, the optical path of the alignment light 38 is away from the plasma generation region 25. Accordingly, it is possible to suppress the alignment light 38 from passing through the second point 292a.

(4) According to the first embodiment, the EUV light concentrating mirror 23a reflects the alignment light 38 in a direction different from the direction orienting from the incident position, on the EUV light concentrating mirror 23a, of the alignment light 38 toward the second focal point 292b. Accordingly, the alignment light 38 can be detected without arranging a beam splitter on the optical path of the EUV light 252a.

(5) According to the first embodiment, the alignment light 38 is made incident on the reflection surface of the EUV light concentrating mirror 23a at the region 231 on the side closer to the second focal point 292b with respect to the plane P1 which is perpendicular to the rotation axis A1 of the spheroid O1 and passes through the plasma generation region 25. Accordingly, since the alignment light 38 is made incident on the region 231 which is less likely to be contaminated by debris of the target substance, the alignment light 38 can be detected with high accuracy.

(6) According to the first embodiment, the optical path of the alignment light 38 is away from the first planar mirror 43. Accordingly, the optical path of the alignment light 38 and the optical path of the EUV light 252a can be separated from each other, and the degree of freedom in installation space of the detection optical system 71b can be improved.

(7) According to the first embodiment, the alignment light 38 is reflected by the EUV light concentrating mirror 23a, passes through the window 39 arranged at the first chamber 2a, and enters the optical sensor 73b. Accordingly, since the alignment light 38 is made enter the optical sensor 73b without passing through the flexible tube 62, the degree of freedom in installation space of the detection optical system 71b can be improved.

(8) According to the first embodiment, the optical path of the EUV light 252a reflected by the EUV light concentrating mirror 23a is away from the window 39. Accordingly, the light can be concentrated onto the second point 292a while suppressing attenuation of the EUV light 252a.

(9) According to the first embodiment, the processor 5 stores the initial position P0 of the alignment light 38 and the initial position Φ0 of the first planar mirror 43, and calculates the target position Φn with respect to the initial position Φ0 of the first planar mirror 43 based on the difference ΔPn between the initial position P0 and the subsequent position Pn of the alignment light 38. Accordingly, even when the alignment light 38 is not made incident on the first planar mirror 43, the deviation of the optical axis of the EUV light 252a can be detected and the first planar mirror 43 can be controlled.

In other respects, the first embodiment is similar to the comparative example.

### 4. EXAMPLE IN WHICH ALIGNMENT LIGHT 38 ENTERS FIRST PLANAR MIRROR 43 ARRANGED IN SECOND CHAMBER 42 p0 4.1 Configuration

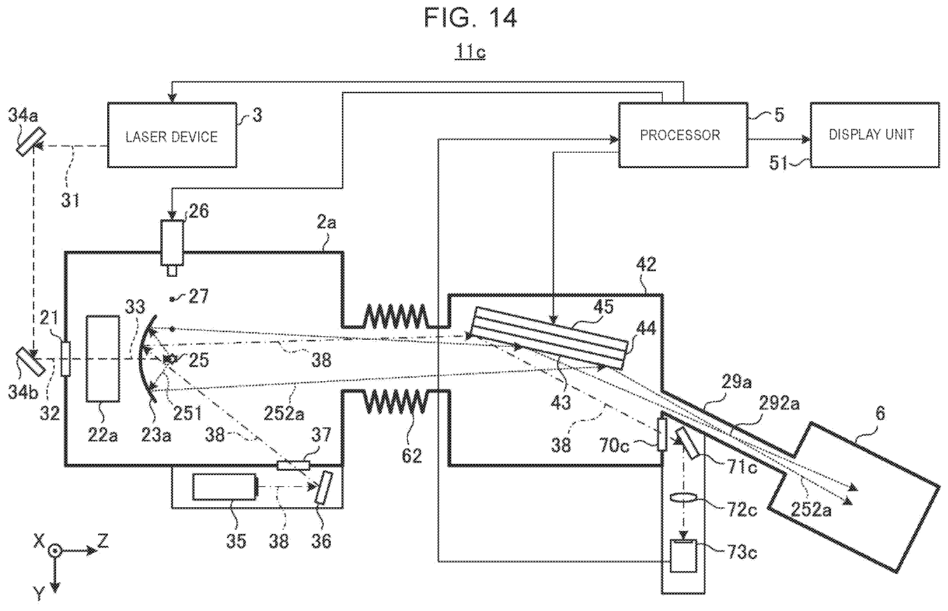

FIG. 14 schematically shows the configuration of an EUV light generation system 11c according to a second embodiment. The EUV light generation system 11c includes a window 70c, a detection optical system 71c, a concentrating optical system 72c, and an optical sensor 73c.

The configurations of the alignment light source 35, the alignment optical system 36, and the window 37 are the same as those in the first embodiment. However, the optical axis of the alignment light 38 defined by the alignment optical system 36 is different from that of the first embodiment.

The first planar mirror 43 is arranged on optical paths of the EUV light 252a reflected by the EUV light concentrating mirror 23a and the alignment light 38 reflected by the EUV light concentrating mirror 23a so that both of the EUV light 252a and the alignment light 38 are incident on the first planar mirror 43.

The window 70c is arranged at the second chamber 42 so as to be positioned on the optical path of the alignment light 38 between the first planar mirror 43 and the detection optical system 71c. The window 70c corresponds to the second window in the present disclosure.

The detection optical system 71c, the concentrating optical system 72c, and the optical sensor 73c are arranged outside the second chamber 42. The concentrating optical system 72c is arranged on the optical path of the alignment light 38 between the detection optical system 71c and the optical sensor 73c. The optical sensor 73c which detects the alignment light 38 is arranged at the focal point of the concentrating optical system 72c. The optical sensor 73c corresponds to the detector in the present disclosure.
4.2 Operation

The alignment light 38 transmitted through the window 37 passes through a position close to the plasma generation region 25 and is incident on the EUV light concentrating mirror 23a. Here, the optical path of the alignment light 38 from the window 37 to the EUV light concentrating mirror 23a is slightly away from the plasma generation region 25, and the alignment light 38 does not pass through the plasma generation region 25.

The alignment light 38 reflected by the EUV light concentrating mirror 23a passes through the inside of the flexible tube 62 similarly to the EUV light 252a, and is incident on the first planar mirror 43. Here, the optical axis of the alignment light 38 reflected by the EUV light concentrating mirror 23a is slightly different from the direction orienting toward the second focal point 292b (see FIG. 4). Therefore, the alignment light 38 reflected by the first planar mirror 43 travels in a direction slightly different from the direction orienting toward the second point 292a. The alignment light 38 is output to the outside of the second chamber 42 by being transmitted through the window 70c and enters the detection optical system 71c. On the other hand, the optical path of the EUV light 252a reflected by the first planar mirror 43 is slightly away from the window 70c, and the EUV light 252a does not enter the window 70c.

The detection optical system 71c causes the alignment light 38 to enter the optical sensor 73c through the concentrating optical system 72c. The concentrating optical system 72c concentrates the alignment light 38 onto the light receiving surface of the optical sensor 73c. The optical sensor 73c obtains the light intensity distribution at the light receiving surface and outputs it to the processor 5.

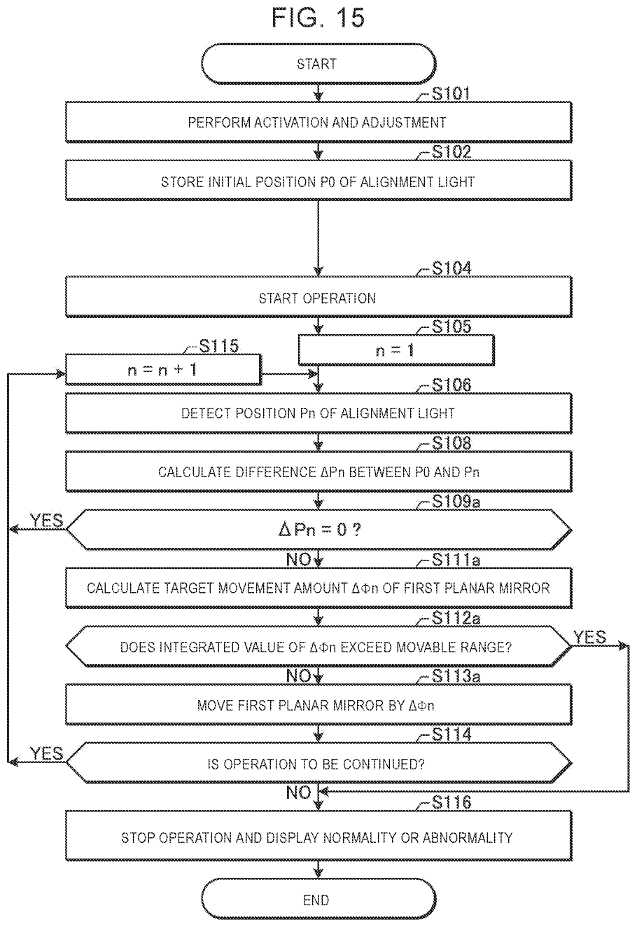

FIG. 5 is a flowchart showing operation of the processor 5 in the second embodiment. The flowchart shown in FIG. 15 includes a procedure of optical axis control of the EUV light 252a using the alignment light 38.

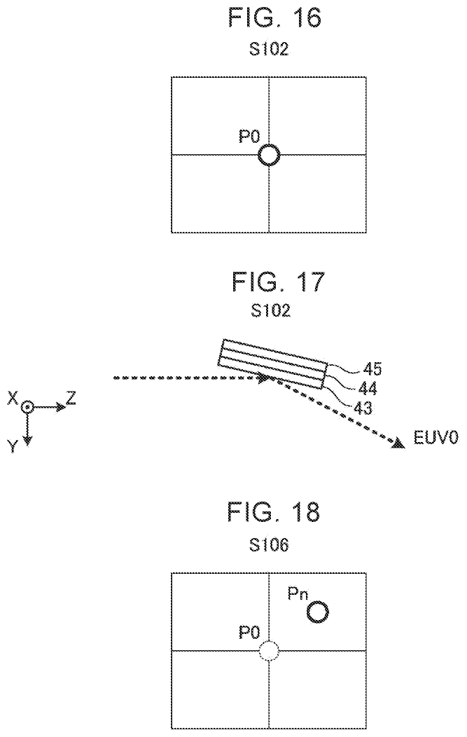

FIGS. 16, 18, 20, and 22 each show an example of the light intensity distribution output from the optical sensor 73c. FIGS. 17, 19, 21, and 23 each show relationship between the position of the first planar mirror 43 and the optical axis of the EUV light 252a.

The processes of S101 and S102 are similar to the corresponding processes in the first embodiment. However, the EUV light generation system 11b according to the first embodiment is replaced with the EUV light generation system 11c according to the second embodiment. FIG. 16 shows an initial position P0 stored in S102. As shown in FIG. 17, when the position Pn of the alignment light 38 is the initial position P0, the optical axis of the EUV light 252a reflected by the first planar mirror 43 is EUV0.

After S102, the processor 5 advances processing to S104. The second embodiment is different from the first embodiment in that the initial position Φ0 of the first planar mirror 43 is not stored.

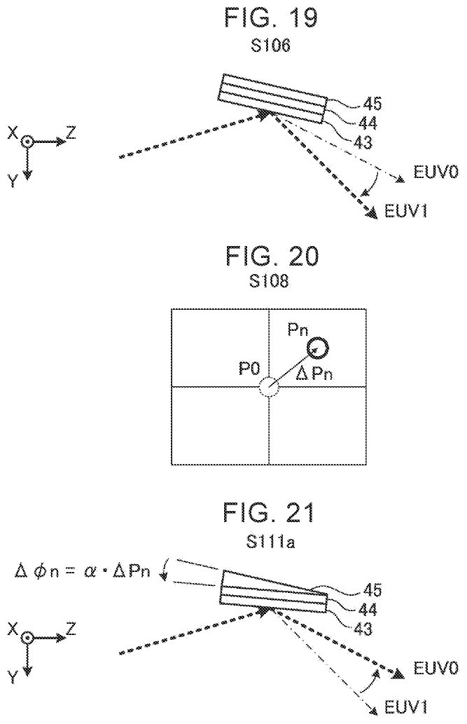

The processes of S104 to S106 are similar to the corresponding processes in the first embodiment. FIG. 18 shows the position Pn of the alignment light 38 newly detected in S106. FIG. 19 shows the new optical axis EUV1 of the EUV light 252a. After S106, the processor 5 advances processing to S108.

In S108, the process of calculating the difference ΔPn between the initial position P0 and the position Pn of the alignment light 38 newly detected by the optical sensor 73c is similar to that in the first embodiment.

FIG. 20 shows ΔPn.

In S109a, the processor 5 determines whether the difference ΔPn is 0 or not. The second embodiment differs from the first embodiment in determining the difference ΔPn between Pn and P0 instead of determining the difference between the position Pn of the alignment light 38 and the previously measured position Pn−1 of the alignment light 38.

When the difference ΔPn is 0 (YES in S109a), the processor 5 advances processing to S115. The processor 5 updates the value of n by adding 1 to the current value of n in S115, and then, returns processing to S106.

When the difference ΔPn is not 0 (NO in S109a), the processor 5 advances processing to S111a.

In S111a, the processor 5 calculates a target movement amount ΔΦn of the first planar mirror 43 by the following equation.

ΔΦn=α*ΔPn

Here, α is a proportional constant.

FIG. 21 shows the target movement amount ΔΦn of the first planar mirror 43. By using the difference ΔPn, it is possible to set the target movement amount ΔΦn of the first planar mirror 43 for returning the optical axis EUV1 of the EUV light 252a.

In S112a, the processor 5 determines whether or not the integrated value of the target movement amount ΔΦn exceeds a movable range of the first planar mirror 43. The integrated value of ΔΦn is the total value of ΔΦn from ΔΦn when the value of n is 1 to the current ΔΦn. When the integrated value exceeds the movable range (YES in S112a), the processor 5 advances processing to S116. When the integrated value is within the movable range (NO in S112a), the processor 5 advances processing to S113a.

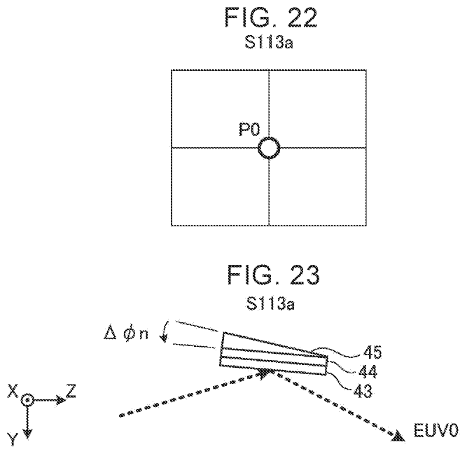

In S113a, the processor 5 controls the actuator 45 to move the first planar mirror 43 by the target movement amount ΔΦn. FIG. 22 shows the light intensity distribution output from the optical sensor 73c after the process in S113a. FIG. 23 shows relationship between the position of the first planar mirror 43 and the optical axis EUV0 of the EUV light 252a after the process in S113a. As shown in FIG. 23, the first planar mirror 43 is moved by the target movement amount ΔΦn, and the optical axis of the EUV light 252a reflected by the first planar mirror 43 is returned to EUV0. Further, as shown in FIG. 22, the position Pn of the alignment light 38 is returned to the initial position P0.

The processes of S114 and S116 are similar to the corresponding processes in the first embodiment. After S116, the processor 5 ends processing of the flowchart.
4.3 Effect

(10) According to the second embodiment, the first planar mirror 43 is arranged on the optical paths of both the EUV light 252a reflected by the EUV light concentrating mirror 23a and the alignment light 38. Accordingly, by detecting the alignment light 38 reflected by the first planar mirror 43, it is possible to detect the deviation of the relative position of the first planar mirror 43 with respect to the EUV light concentrating mirror 23a and to control posture of the first planar mirror 43.

(11) According to the second embodiment, the alignment light 38 is reflected by the first planar mirror 43, passes through the window 70c arranged at the second chamber 42, and enters the optical sensor 73c. Accordingly, the alignment light 38 can be detected outside the second chamber 42.

(12) According to the second embodiment, the optical path of the EUV light 252a reflected by the first planar mirror 43 is away from the window 70c. Accordingly, the light can be concentrated onto the second point 292a while suppressing attenuation of the EUV light 252a.

(13) According to the second embodiment, the processor 5 stores the initial position P0 of the alignment light 38, and calculates the target movement amount ΔΦn of the first planar mirror 43 based on the difference ΔPn between the initial position P0 and the subsequent position Pn of the alignment light 38. Accordingly, by controlling the first planar mirror 43 so as to return the position Pn of the alignment light 38 to the initial position P0, the optical axis of the EUV light 252a can be stabilized.

In other respects, the second embodiment is similar to the first embodiment.

### 5. EXAMPLE IN WHICH ALIGNMENT LIGHT 38 ENTERS SECOND PLANAR MIRROR 46 ARRANGED IN SECOND CHAMBER 42

5.1 Configuration

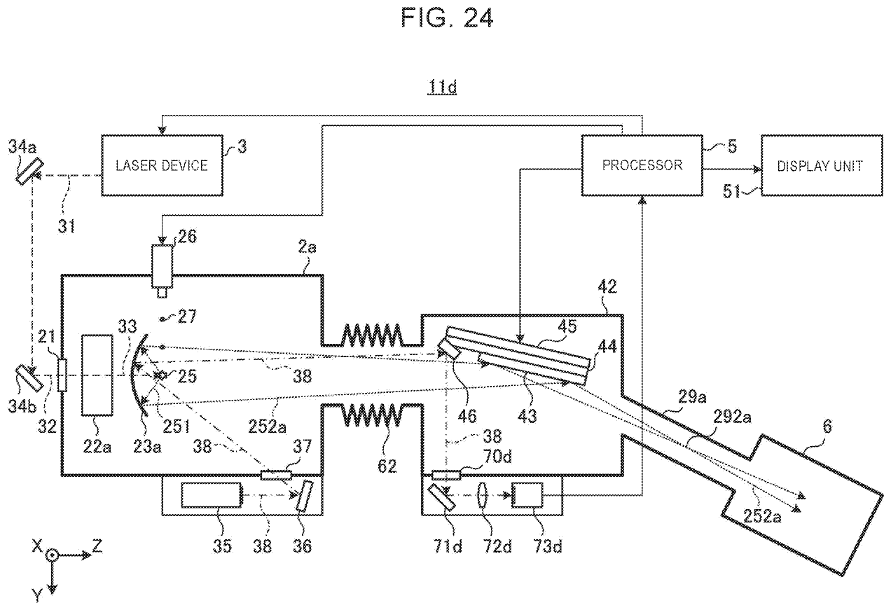

FIG. 24 schematically shows the configuration of an EUV light generation system 11d according to a third embodiment. The EUV light generation system 11d includes a second planar mirror 46, a window 70d, a detection optical system 71d, a concentrating optical system 72d, and an optical sensor 73d.

Configurations of the alignment light source 35, the alignment optical system 36, and the window 37 are the same as those in the second embodiment.

The second planar mirror 46 is arranged in the second chamber 42 on the optical path of the alignment light 38 between the EUV light concentrating mirror 23a and the optical sensor 73d. The first and second planar mirrors 43, 46 are arranged such that directions of reflection surfaces thereof are different from each other. The holder 44 which supports the first planar mirror 43 is commonly used to support the second planar mirror 46. According to the above, the actuator 45 integrally changes posture of the first and second planar mirrors 43, 46, while maintaining the difference between the directions of the reflection surfaces thereof.

The window 70d is arranged at the second chamber 42 so as to be positioned on the optical path of the alignment light 38 between the second planar mirror 46 and the detection optical system 71d. The window 70d corresponds to the third window in the present disclosure. The detection optical system 71d, the concentrating optical system 72d, and the optical sensor 73d are arranged outside the second chamber 42. The concentrating optical system 72d is arranged on the optical path of the alignment light 38 between the detection optical system 71d and the optical sensor 73d. The optical sensor 73d which detects the alignment light 38 is arranged at the focal point of the concentrating optical system 72d. The optical sensor 73d corresponds to the detector in the present disclosure.
5.2 Operation

The alignment light 38 reflected by the EUV light concentrating mirror 23a passes through the inside of the flexible tube 62 similarly to the EUV light 252a, but is incident on the second planar mirror 46 without being incident on the first planar mirror 43. Although the optical axis of the alignment light 38 incident on the second planar mirror 46 is slightly different from the optical axis of the EUV light 252a incident on the first planar mirror 43, the optical axis of the alignment light 38 reflected by the second planar mirror 46 is greatly different from the optical axis of the EUV light 252a reflected by the first planar mirror 43. The alignment light 38 is output to the outside of the second chamber 42 by being transmitted through the window 70d arranged at a position away from the connection portion 29a, and enters the detection optical system 71d.

On the other hand, the optical path of the EUV light 252a reflected by the EUV light concentrating mirror 23a is away from the second planar mirror 46, and the EUV light 252a is not incident on the second planar mirror 46. Further, the optical path of the EUV light 252a reflected by the first planar mirror 43 is away from the window 70d, and the EUV light 252a does not enter the window 70d.

The detection optical system 71d causes the alignment light 38 to enter the optical sensor 73d through the concentrating optical system 72d. The concentrating optical system 72d concentrates the alignment light 38 onto the light receiving surface of the optical sensor 73d. The optical sensor 73d obtains the light intensity distribution at the light receiving surface and outputs it to the processor 5.

The operation of the processor 5 in the third embodiment is similar to the operation of the processor 5 in the second embodiment described with reference to FIG. 15. However, the EUV light generation system 11c according to the second embodiment is replaced with the EUV light generation system 11d according to the third embodiment.
5.3 Effect

(14) According to the third embodiment, the second planar mirror 46 is arranged in the second chamber 42 on the optical path of the alignment light 38 between the EUV light concentrating mirror 23a and the optical sensor 73d. Accordingly, since the alignment light 38 can be reflected by the second planar mirror 46 in a direction different from the direction of the EUV light 252a reflected by the first planar mirror 43, the degree of freedom in installation space of the detection optical system 71d can be improved.

(15) According to the third embodiment, the actuator 45 integrally changes posture of the first and second planar mirrors 43, 46. Accordingly, it is possible to detect the deviation of the relative positions of the first and second planar mirrors 43, 46 with respect to the EUV light concentrating mirror 23a and to control posture of the first planar mirror 43.

(16) According to the third embodiment, the alignment light 38 is reflected by the second planar mirror 46, passes through the window 70d arranged at the second chamber 42, and enters the optical sensor 73d. Accordingly, the alignment light 38 can be detected outside the second chamber 42.

(17) According to the third embodiment, the optical path of the EUV light 252a reflected by the first planar mirror 43 is away from the window 70d. Accordingly, the light can be concentrated onto the second point 292a while suppressing attenuation of the EUV light 252a. Further, the degree of freedom in installation space for components around the window 70d can be improved.

(18) According to the third embodiment, the optical path of the EUV light 252a reflected by the EUV light concentrating mirror 23a is away from the second planar mirror 46. Accordingly, the light can be concentrated onto the second point 292a while suppressing attenuation of the EUV light 252a.

In other respects, the third embodiment is similar to the second embodiment.

### 6. OTHERS

FIG. 25 schematically shows the configuration of an exposure apparatus 6a connected to the EUV light generation system lib.

In FIG. 25, the exposure apparatus 6a as the EUV light utilization apparatus 6 (see FIG. 1) includes a mask irradiation unit 608 and a workpiece irradiation unit 609. The mask irradiation unit 608 illuminates, via a reflection optical system, a mask pattern of a mask table MT with the EUV light incident from the EUV light generation system lib. The workpiece irradiation unit 609 images the EUV light reflected by the mask table MT onto a workpiece (not shown) arranged on a workpiece table WT via a reflection optical system. The workpiece is a photosensitive substrate such as a semiconductor wafer on which photoresist is applied. The exposure apparatus 6a synchronously translates the mask table MT and the workpiece table WT to expose the workpiece to the EUV light reflecting the mask pattern. Through the exposure process as described above, a device pattern is transferred onto the semiconductor wafer, thereby an electronic device can be manufactured.

FIG. 26 schematically shows the configuration of an inspection apparatus 6b connected to the EUV light generation system 11b.

In FIG. 26, the inspection apparatus 6b as the EUV light utilization apparatus 6 (see FIG. 1) includes an illumination optical system 603 and a detection optical system 606. The Illumination optical system 603 reflects the EUV light incident from the EUV light generation system 11b to illuminate a mask 605 placed on a mask stage 604. Here, the mask 605 conceptually includes a mask blank before a pattern is formed. The detection optical system 606 reflects the EUV light from the illuminated mask 605 and forms an image on a light receiving surface of a detector 607. The detector 607 having received the EUV light obtains the image of the mask 605. The detector 607 is, for example, a time delay integration (TDI) camera. A defect of the mask 605 is inspected based on the image of the mask 605 obtained by the above-described process, and a mask suitable for manufacturing an electronic device is selected using the inspection result. Then, the electronic device can be manufactured by exposing and transferring the pattern formed on the selected mask onto the photosensitive substrate using the exposure apparatus 6a.

In FIGS. 25 and 26, the EUV light generation system 11c or 11d may be used instead of the EUV light generation system 11b.

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. An extreme ultraviolet light generation apparatus, comprising:
a first chamber;
an EUV light concentrating mirror arranged in the first chamber and configured to concentrate extreme ultraviolet light generated at a first point in the first chamber onto a second point;
a first planar mirror arranged on an optical path of the extreme ultraviolet light reflected by the EUV light concentrating mirror;
a second chamber accommodating the first planar mirror;
a flexible tube arranged between the first and second chambers;
an alignment optical system arranged at the first chamber and configured to cause alignment light to be incident on the EUV light concentrating mirror;
a detector arranged at the second chamber and configured to detect the alignment light reflected by the EUV light concentrating mirror;
an actuator configured to change posture of the first planar mirror; and
a processor configured to control the actuator based on output of the detector.

2. The extreme ultraviolet light generation apparatus according to claim 1,
wherein the first planar mirror is located on the optical path of the extreme ultraviolet light between the EUV light concentrating mirror and the second point.

3. The extreme ultraviolet light generation apparatus according to claim 1,
wherein the EUV light concentrating mirror is a spheroidal mirror having a first focal point corresponding to the first point and a second focal point farther from the EUV light concentrating mirror than the first focal point, and
the EUV light concentrating mirror reflects the alignment light in a direction different from the direction orienting toward the second focal point from an incident position of the alignment light on the EUV light concentrating mirror,

4. The extreme ultraviolet light generation apparatus according to claim 1,
wherein the EUV light concentrating mirror is a spheroidal mirror having a first focal point corresponding to the first point, a second focal point farther from the EUV light concentrating mirror than the first focal point, and a virtual rotation axis passing through the first and second focal points, and
the alignment optical system causes the alignment light to be incident on a reflection surface of the EUV light concentrating mirror at a region on a side closer to the second focal point with respect to a virtual plane which is perpendicular to the rotation axis and passes through the first focal point.

5. The extreme ultraviolet light generation apparatus according to claim 1,
wherein an optical path of the alignment light is away from the first point.

6. The extreme ultraviolet light generation apparatus according to claim 1,
wherein an optical path of the alignment light is away from the first planar mirror.

7. The extreme ultraviolet light generation apparatus according to claim 1,
wherein the first chamber includes a first window, and
the alignment light is reflected by the EUV light concentrating mirror, passes through the first window, and enters the detector.

8. The extreme ultraviolet light generation apparatus according to claim 7,
wherein the optical path of the extreme ultraviolet light reflected by the EUV light concentrating mirror is away from the first window.

9. The extreme ultraviolet light generation apparatus according to claim 7,
wherein the processor stores a first initial position of the alignment light detected by the detector and a second initial position of the first planar mirror, calculates a target position of the first planar mirror relative to the second initial position based on a difference between the first initial position and a position of the alignment light subsequently detected by the detector, and controls the actuator based on the target position.

10. The extreme ultraviolet light generation apparatus according to claim 1,
wherein the first planar mirror is arranged on both of optical paths of the extreme ultraviolet light and the alignment light both reflected by the EUV light concentrating mirror.

11. The extreme ultraviolet light generation apparatus according to claim 1,
wherein the second chamber includes a second window, and
the alignment light is reflected by the first planar mirror, passes through the second window, and enters the detector.

12. The extreme ultraviolet light generation apparatus according to claim 11,
wherein the optical path of the extreme ultraviolet light reflected by the first planar mirror is away from the second window.

13. The extreme ultraviolet light generation apparatus according to claim 11,
wherein the processor stores an initial position of the alignment light detected by the detector, calculates a target movement amount of the first planar mirror based on a difference between the initial position and a position of the alignment light subsequently detected by the detector, and controls the actuator based on the target movement amount.

14. The extreme ultraviolet light generation apparatus according to claim 1, further comprising:
a second planar mirror arranged in the second chamber on an optical path of the alignment light between the EUV light concentrating mirror and the detector.

15. The extreme ultraviolet light generation apparatus according to claim 14,
wherein the actuator integrally changes posture of the first and second planar mirrors.

16. The extreme ultraviolet light generation apparatus according to claim 14,
wherein the second chamber includes a third window, and
the alignment light is reflected by the second planar mirror, passes through the third window, and enters the detector.

17. The extreme ultraviolet light generation apparatus according to claim 16,
wherein the optical path of the extreme ultraviolet light reflected by the first planar mirror is away from the third window.

18. The extreme ultraviolet light generation apparatus according to claim 14,
wherein the optical path of the extreme ultraviolet light reflected by the EUV light concentrating mirror is away from the second planar mirror.

19. An electronic device manufacturing method, comprising:
generating extreme ultraviolet light using an extreme ultraviolet light generation apparatus;
outputting the extreme ultraviolet light to an exposure apparatus; and
exposing a photosensitive substrate to the extreme ultraviolet light in the exposure apparatus to manufacture an electronic device,
the extreme ultraviolet light generation apparatus including:
a first chamber;
an EUV light concentrating mirror arranged in the first chamber and configured to concentrate the extreme ultraviolet light generated at a first point in the first chamber onto a second point;
a first planar mirror arranged on an optical path of the extreme ultraviolet light reflected by the EUV light concentrating mirror;
a second chamber accommodating the first planar mirror;
a flexible tube arranged between the first and second chambers;
an alignment optical system arranged at the first chamber and configured to cause alignment light to be incident on the EUV light concentrating mirror;
a detector arranged at the second chamber and configured to detect the alignment light reflected by the EUV light concentrating mirror;
an actuator configured to change posture of the first planar mirror; and
a processor configured to control the actuator based on output of the detector.

20. An electronic device manufacturing method, comprising:
inspecting a defect of a mask by irradiating the mask with extreme ultraviolet light generated by an extreme ultraviolet light generation apparatus;
selecting a mask using a result of the inspection; and
exposing and transferring a pattern formed on the selected mask onto a photosensitive substrate,
the extreme ultraviolet light generation apparatus including:
a first chamber;
an EUV light concentrating mirror arranged in the first chamber and configured to concentrate the extreme ultraviolet light generated at a first point in the first chamber onto a second point;
a first planar mirror arranged on an optical path of the extreme ultraviolet light reflected by the EUV light concentrating mirror;
a second chamber accommodating the first planar mirror;
a flexible tube arranged between the first and second chambers;
an alignment optical system arranged at the first chamber and configured to cause alignment light to be incident on the EUV light concentrating mirror;
a detector arranged at the second chamber and configured to detect the alignment light reflected by the EUV light concentrating mirror;
an actuator configured to change posture of the first planar mirror; and
a processor configured to control the actuator based on output of the detector.
